(19) United States
(12) Patent Application Publication
(10) Pub. No.: US 2002/0096761 A1
(43) Pub. Date: Jul. 25, 2002

(54) STRUCTURE OF STACKED INTEGRATED CIRCUITS AND METHOD FOR MANUFACTURING THE SAME

(76) Inventors: Wen Chuan Chen, Hsinchu Hsien (TW); Kuo Feng Peng, Hsinchu Hsien (TW); C. H. Chou, Hsinchu Hsien (TW); Allis Chen, Hsinchu Hsien (TW); Nai Hua Yeh, Hsinchu Hsien (TW); Yen Cheng Huang, Hsinchu Hsien (TW); Fu Yung Huang, Hsinchu Hsien (TW); Chief Lin, Hsinchu Hsien (TW); C. S. Cheng, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/770,081

(22) Filed: Jan. 24, 2001

(51) Int. Cl. H01L 23/34; H01L 21/50

(52) U.S. Cl. 257/723; 438/109

(57) ABSTRACT

A structure of stacked integrated circuits arranged on a circuit board includes a substrate, a lower integrated circuit, a plurality of wirings, a passivation layer, and an upper integrated circuit. The substrate has a first surface formed with signal input terminals, and a second surface formed with signal output terminals for electrically connecting to the circuit board. The lower integrated circuit has a first surface and a second surface. The first surface of the lower integrated circuit is adhered onto the first surface of the substrate. The second surface of the lower integrated circuit is formed with a plurality of bonding pads. The wirings each includes a first end and a second end opposite to the first end. The first ends of the wirings are electrically connected to the bonding pads of the lower integrated circuit, and the second ends of the wirings are electrically connected to the signal input terminals of the substrate, respectively. The passivation layer is coated on the second surface of the lower integrated circuit for sealing the plurality of wirings. The upper integrated circuit is adhered on the passivation layer to form a stack with the lower integrated circuit. According to the structure, the wirings are free from being pressed by the upper integrated circuit, the stacking processes can be facilitated, and the manufacturing costs can be effectively lowered.

### BACKGROUND OF THE INVENTION

1. Field of the Invention

The invention relates to a structure of stacked integrated circuits and method for manufacturing the same, in particular, to a structure of stacked integrated circuits in which integrated circuits can be effectively stacked so as to facilitate the manufacturing processes.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

To meet the demands of manufacturing small, thin, and light products, a lot of integrated circuits can be stacked. However, when stacking a lot of integrated circuits, the upper integrated circuit will contact and press the wirings of the lower integrated circuit. In this case, the signal transmission to or from the lower integrated circuit is easily influenced.

Referring to FIG. 1, a structure of stacked integrated circuits includes a substrate 10, a lower integrated circuit 12, an upper integrated circuit 14, a plurality of wirings 16, and an isolation layer 18. The lower integrated circuit 12 is located on the substrate 10. The isolation layer 18 is located on the lower integrated circuit 12. The upper integrated circuit 14 is stacked on the isolation layer 18. That is, the upper integrated circuit 14 is stacked above the lower integrated circuit 12 with the isolation layer 18 interposed between the integrated circuits 12 and 14. Thus, a proper gap 20 is formed between the lower integrated circuit 12 and the upper integrated circuit 14. According to this structure, the plurality of wirings 16 can be electrically connected to the edge of the lower integrated circuit 12. Furthermore, the plurality of wirings 16 connecting the substrate 10 to the lower integrated circuit 12 are free from being pressed when stacking the upper integrated circuit 14 above the lower integrated circuit 12.

However, the above-mentioned structure has the disadvantages to be described hereinbelow. During the manufacturing processes, the isolation layer 18 has to be manufactured in advance, and then, it is adhered to the lower integrated circuit 12. Thereafter, the upper integrated circuit 14 has to be adhered on the isolation layer 18. As a result, the manufacturing processes are complicated, and the manufacturing costs are high.

To solve the above-mentioned problems, it is necessary for the invention to provide a structure of stacked integrated circuits in order to improve the stacking processes of the integrated circuits, facilitate the manufacturing processes, and lower down the manufacturing costs.

### SUMMARY OF THE INVENTION

It is therefore an object of the invention to provide a structure of stacked integrated circuits and method for manufacturing the same in order to effectively stack the integrated circuits and increase the manufacturing speed.

It is therefore another object of the invention to provide a structure of stacked integrated circuits and method for manufacturing the same capable of simplifying the stacking processes by arranging an isolation layer on the integrated circuit simultaneously.

According to one aspect of the invention, a structure of stacked integrated circuits arranged on a circuit board includes a substrate, a lower integrated circuit, a plurality of wirings, a passivation layer, and an upper integrated circuit. The substrate has a first surface formed with signal input terminals, and a second surface formed with signal output terminals for electrically connecting to the circuit board. The lower integrated circuit has a first surface and a second surface. The first surface of the lower integrated circuit is adhered onto the first surface of the substrate. The second surface of the lower integrated circuit is formed with a plurality of bonding pads. The wirings each includes a first end and a second end opposite to the first end. The first ends of the wirings are electrically connected to the bonding pads of the lower integrated circuit, and the second ends of the wirings are electrically connected to the signal input terminals of the substrate, respectively. The passivation layer is coated on the second surface of the lower integrated circuit for sealing the plurality of wirings. The upper integrated circuit is adhered on the passivation layer to form a stack with the lower integrated circuit.

According to the structure, the wirings are free from being pressed by the upper integrated circuit, the stacking processes can be facilitated, and the manufacturing costs can be effectively lowered.

### BRIEF DESCRIPTION OF THE DRAWINGS

FIG. 1 is a cross-sectional view showing a conventional structure of stacked integrated circuits.

FIG. 2 is a cross-sectional view showing a structure of stacked integrated circuits according to a first embodiment of the invention.

FIG. 3 is a schematic illustration showing the structure of stacked integrated circuits according to a second embodiment of the invention.

FIG. 4 is a schematic illustration showing the structure of stacked integrated circuits according to a third embodiment of the invention.

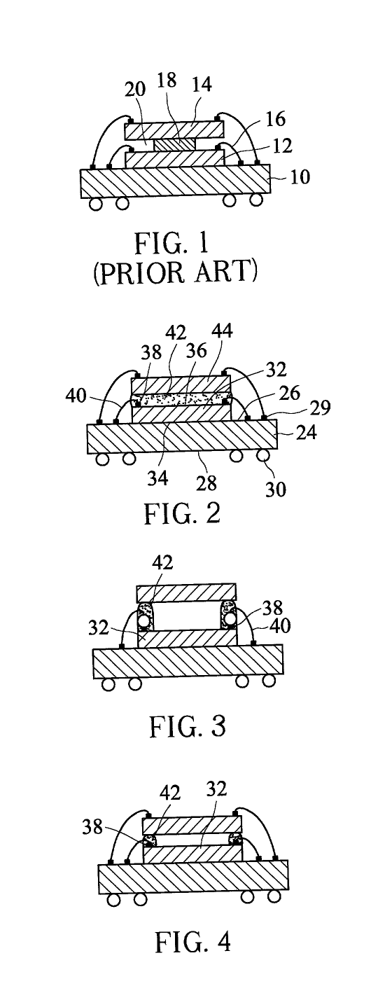

### DETAIL DESCRIPTION OF THE INVENTION

The embodiments of the invention will be described with reference to the drawings.

Referring to FIG. 2, the structure of stacked integrated circuits according to the first embodiment of the invention includes a substrate 24, a lower integrated circuit 32, a plurality of wirings 40, a passivation layer 42, and an upper integrated circuit 44.

The substrate 24 has a first surface 26 and a second surface 28. The first surface 26 is formed with a plurality of signal input terminals 29 through which the signals from the integrated circuits can be transmitted to the substrate 24. The second surface 28 is formed with a plurality of signal output terminals through which the signals can be transmitted to the circuit board. The signal output terminals may be a plurality of metallic balls 30 arranged in the form of a ball grid array (BGA).

The lower integrated circuit 32 is formed with a first surface 34 and a second surface 36. The first surface 34 of the lower integrated circuit 32 is adhered onto the first surface 26 of the substrate 24. The second surface 36 of the lower integrated circuit 32 is formed with a plurality of bonding pads 38.

First ends of the plurality of wirings 40 are electrically connected to the bonding pads 38 of the lower integrated circuit 32, while second ends of the wirings 40 are electrically connected to the signal input terminals 29 of the substrate 24, respectively. Thus, the signals from the lower integrated circuit 32 can be transmitted to the second surface 28 of the substrate 24. The wirings 40 can be bonded to the bonding pads 38 of the lower integrated circuit 32 by way of wedge bonding, respectively. The first ends of the wirings 40 are located on the periphery of the second surface 36 of the lower integrated circuit 32.

Referring to FIG. 3, the plurality of wirings 40 can also be electrically connected to the bonding pads 38 of the lower integrated circuit 32 by way of ball bonding, respectively.

The passivation layer 42 is coated over the whole second surface 36 of the lower integrated circuit 32 for sealing and covering the plurality of wirings 40. Thus, the upper integrated circuit 44 cannot contact or press the wirings 40. Moreover, the passivation layer 42 is adhesive so that the upper integrated circuit 44 can be adhered on the lower integrated circuit 32 by the passivation layer 42.

The upper integrated circuit 44 is adhered on the passivation layer 42 to form a stack with the lower integrated circuit 32. At this time, the wirings 40 are covered by the passivation layer 42 so that the wirings 40 are free from being pressed or contacted with the upper integrated circuit 44.

Referring to FIG. 4, it is also possible that the passivation layer 42 is only coated on the bonding pads 38 of the lower integrated circuit 32 for sealing the plurality of wirings 40, in order to save the materials of the passivation layer 42.

According to the above-mentioned structures and manufacturing method of stacked integrated circuits of the invention, the following advantages can be obtained.

1. Since the wirings 40 and the bonding pads 38 of the lower integrated circuit 32 are packed by the passivation layer 42, the wirings 40 will never be pressed by the upper integrated circuit 44 when stacking the upper integrated circuit 44 above the lower integrated circuit 32.

2. Since the passivation layer 42 can be coated onto the lower integrated circuit 32 by a general coater, the manufacturing processes can be facilitated.

3. Since the passivation layer 42 can be coated using a general coater, it is not necessary to prepare another bonding apparatus for bonding the conventional isolation layer 18. Thus, the manufacturing costs can be lowered.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A structure of stacked integrated circuits arranged on a circuit board, comprising:
a substrate having a first surface and a second surface, the first surface being formed with signal input terminals, the second surface being formed with signal output terminals for electrically connecting to the circuit board;
a lower integrated circuit having a first surface and a second surface, the first surface of the lower integrated circuit being adhered onto the first surface of the substrate, the second surface of the lower integrated circuit being formed with a plurality of bonding pads;
a plurality of wirings each includes a first end and a second ends opposite to the first end, the first ends of the wirings being electrically connected to the bonding pads of the lower integrated circuit, and the second ends of the wirings being electrically connected to the signal input terminals of the substrate, respectively;
a passivation layer coated on the second surface of the lower integrated circuit for sealing the plurality of wirings; and
an upper integrated circuit adhered on the passivation layer to form a stack with the lower integrated circuit.

2. The structure of stacked integrated circuits according to claim 1, wherein the signal output terminals of the substrate are metallic balls arranged in the form of a ball grid array (BGA).

3. The structure of stacked integrated circuits according to claim 1, wherein the plurality of wirings are electrically connected to the periphery of the second surface of the lower integrated circuit.

4. The structure of stacked integrated circuits according to claim 3, wherein the plurality of wirings are electrically connected to the lower integrated circuit by way of wedge bonding.

5. The structure of stacked integrated circuits according to claim 1, wherein the passivation layer is only coated on the bonding pads of the lower integrated circuit to which the wirings are connected.

6. The structure of stacked integrated circuits according to claim 1, wherein the passivation layer is coated over the whole second surface of the lower integrated circuit.

7. The structure of stacked integrated circuits according to claim 1, wherein the plurality of wirings are bonded onto the bonding pads of the lower integrated circuit by way of ball bonding.

8. The structure of stacked integrated circuits according to claim 1, wherein the passivation layer is adhesive so as to adhere the upper integrated circuit to the lower integrated circuit.

9. A method for manufacturing a structure of stacked integrated circuits, comprising the steps of:
providing a substrate;
providing a lower integrated circuit arranged on the substrate;
electrically connecting the lower integrated circuit to the substrate via a plurality of wirings;
coating a passivation layer onto the lower integrated circuit and sealing the plurality of wirings; and
stacking an upper integrated circuit on the passivation layer to stack above the lower integrated circuit.

10. The method for manufacturing a structure of stacked integrated circuits according to claim 9, wherein the plurality of wirings are electrically connected to the periphery of the second surface of the lower integrated circuit.

11. The method for manufacturing a structure of stacked integrated circuits according to claim 9, wherein the substrate is a BGA substrate.

12. The method for manufacturing a structure of stacked integrated circuits according to claim 9, wherein the plurality of wirings are electrically connected to the lower integrated circuit by way of wedge bonding.

13. The method for manufacturing a structure of stacked integrated circuits according to claim 9, wherein the plurality of wirings are electrically connected to the bonding pads of the lower integrated circuit by way of ball bonding.

14. The method for manufacturing a structure of stacked integrated circuits according to claim 9, wherein the passivation layer is coated on the bonding pads of the lower integrated circuit to which the wirings are connected.

15. The method for manufacturing a structure of stacked integrated circuits according to claim 9 wherein the passivation layer is coated over the whole second surface of the lower integrated circuit.
